(19) United States
(12) Patent Application Publication
(10) Pub. No.: US 2025/0115780 A1
(43) Pub. Date: Apr. 10, 2025

(54) COMPOSITIONS FOR FORMING ANTISTATIC COATINGS AND ARTICLES COATED WITH THE COMPOSITIONS

(71) Applicant: W. L. Gore & Associates GmbH, Putzbrunn (DE)

(72) Inventor: Amadeus Wiesemann, Redmitzhembach (DE)

(21) Appl. No.: 18/887,969

(22) Filed: Sep. 17, 2024

Related U.S. Application Data
(62) Division of application No. 16/962,475, filed on Jul. 15, 2020, now abandoned.

(51) Int. Cl. C08J 7/044; C08F 8/44; C08F 214/26; C09D 5/24; C09D 127/18

(52) U.S. Cl. CPC C09D 127/18; C08F 28/00; C08J 7/043; C08J 7/044; C09D 5/00; C09D 141/00; C09J 7/29; H01B 1/122; H01B 7/02; H05K 9/0079; C08F 2810/00; C09J 2203/326; C09J 2427/006; C09J 2481/006

(57) ABSTRACT

This invention relates to a coating composition comprising an ionomer having a polymer backbone and side chains, the side chains comprising ionic groups, wherein the ionic groups are sulfonic acid groups and sulfonate groups, from 50 to 95% of the total number of sulfonic acid groups and sulfonate groups are in the sulfonate form, and the sulfonate groups have counter ions M selected from the group consisting of lithium, sodium, magnesium, calcium, and mixtures thereof. This invention also relates to an article comprising a polymeric substrate having an antistatic coating thereon, wherein the antistatic coating is formed from the inventive coating composition. The article may be a cable, a cable cover or a cable jacket.

### BACKGROUND

This invention relates to a coating composition comprising an ionomer for the formation of an antistatic coating, to an article having an electrostatic coating formed from the composition, in particular to a cable having a coating or jacket formed from the composition, and to the use of an ionomer having sulfonic acid groups and sulfonate groups for forming an electrostatic coating.

Articles made from electrically non-conductive materials such as fluoropolymers, and articles coated with electrically non-conductive materials have a tendency to build-up electric charge at the surfaces thereof, for example due to the influence of friction or electrical fields. The charges are stored on the surface and may discharge under certain conditions, leading to undesirable effects. Therefore, attempts have been made to prevent build-up of electric charges, and a well-known method is to provide non-conductive surfaces with an antistatic coating (also called electrostatic dissipative coating or electrostatic discharge coating) which reduces surface resistance.

In order to achieve sufficient conductivity of the antistatic coatings, it is known to add electrically conductive particles to the coating material, for example metallic particles, carbon black or graphite. EP 2 145 916 B1 discloses the use of nanoparticles of colloidal organic salts, organic colloidal polymers, polystyrene sulfonate, dyes and inks, and of intrinsically conducting polymers. The nanoparticles may act as counter ionic agent of an ionic fluoropolymer forming the antistatic coating.

Antistatic coatings comprising electrically conductive particles have the disadvantage that the particles can be released due to wear, for example when an article is subjected to repeated flexing and bending or abrasion conditions. Loss of electrically conductive particles leads to deterioration of the antistatic properties of the antistatic coating over time. Furthermore, the released conductive particles may cause problems, in particular in clean rooms. In semi-conductor manufacturing and testing procedures, for example, released conductive particles may cause electrical shorts in semiconductor microcircuits.

Other electrically conductive materials such as salts or dyes may be leached out from the antistatic coating during use, also leading to deterioration of the antistatic properties.

U.S. Pat. No. 9,534, 159 B2 discloses antistatic coatings comprising an ionic fluoropolymer having ionic groups such as carboxylic acid groups, phosphoric acid groups, and sulfonic acid groups. The ionic groups are not in a salt form, but in the acid form. Acid based ionomers provide good electrical conductivity, but due to their high reactivity and acidity they tend to react with air constituents and mating surfaces, leading to surface corrosion. As a consequence of the unintended reactivity and interaction, coatings containing acid based ionomers show strong discoloration and turn to a brownish or black color over time.

In an attempt to address the severe drawbacks of acid based ionomers, EP 0 419 579 B1 discloses perfluorosulfonic acid polymers and perfluorocarboxylic acid polymers wherein the acid groups are fully converted into a metal salt form, i.e. the polymer does no longer comprise acid groups, but only sulfonate and carboxylate groups with metal counter ions. While these salt forms are less corrosive than the corresponding acid forms, the salt forms show typically orders of magnitude lower surface conductivity compared to the respective salt forms. Another disadvantage of salt forms is their brittleness which causes particulation of antistatic coatings under flexing and bending conditions. This lack in performance limits applicability of salt forms.

U.S. Pat. No. 8,497,326 B2 discloses ionomer compositions having antistatic properties, wherein the ionomers have carboxylic acid moieties which are partially in the form of potassium and cesium salts. Thus, the ionomers comprise both carboxylic acid groups and carboxylate groups, the counter ions of the carboxylate groups being cesium and potassium.

It has been found by the present inventor that all ionomers used in the prior art for providing antistatic properties, be they in the acid form or in the salt form, have severe disadvantages or, at least, do not provide a combination of properties as required for challenging applications, for example in semiconductor manufacturing procedures.

Semiconductor manufacturing procedures require a very high yield in every intermediate step to guarantee overall high throughput and product quality. Examples for those procedures are inspection and assembly routines for computer chips and flat panel displays. Due to the drastic effects of single failures, e.g. on a large thin film transistor display, effective measures have to be implemented to exclude impurities and particles, and to prevent unintended electrostatic discharges. Especially assembly and testing procedures are critical areas as they involve moving parts for positioning sensors or placing electronic components. Due to the possibility of friction and wear of moving parts both the generation of particles and electric charge build up is expected. At present, no antistatic coating is available which fully satisfies the needs for applications requiring a combination of properties of antistatic coatings.

There is a need for antistatic coatings overcoming at least some of the disadvantages associated with prior art antistatic coatings. The present invention satisfies this need.

### BRIEF DESCRIPTION OF THE DRAWINGS

FIG. 1A is a chart showing the relationship between surface resistance and coating weight for a first exemplary coating.

FIG. 1B is a chart showing the relationship between surface resistance and coating weight for a second exemplary coating.

FIG. 1C is a chart showing the relationship between surface resistance and coating weight for a third exemplary coating.

FIG. 1D is a chart showing the relationship between surface resistance and coating weight for a fourth exemplary coating.

FIG. 1E is a chart showing the relationship between surface resistance and coating weight for a fifth exemplary coating.

FIG. 1F is a chart showing the relationship between surface resistance and coating weight for a sixth exemplary coating.

FIG. 1G is a chart showing the relationship between surface resistance and coating weight for a seventh exemplary coating.

FIG. 1H is a chart showing the relationship between surface resistance and coating weight for an eighth exemplary coating.

FIG. 1I is a chart showing the relationship between surface resistance and coating weight for a ninth exemplary coating.

FIG. 1J is a chart showing the relationship between surface resistance and coating weight for a tenth exemplary coating.

FIG. 1K is a chart showing the relationship between surface resistance and coating weight for an eleventh exemplary coating.

FIG. 1L is a chart showing the relationship between surface resistance and coating weight for a twelfth exemplary coating.

FIG. 1M is a chart showing the relationship between surface resistance and coating weight for a thirteenth exemplary coating.

FIG. 1N is a chart showing the relationship between surface resistance and coating weight for a fourteenth exemplary coating.

FIG. 1O is a chart showing the relationship between surface resistance and coating weight for a fifteenth exemplary coating.

FIG. 2 is a chart showing the relationship between surface resistance and percentage of sulfonic acid groups with the remainder of sulfonate groups having lithium as a counter ion.

FIG. 3 is a chart showing the relationship between surface resistance and percentage of sulfonic acid groups with the remainder of sulfonate groups having sodium as a counter ion.

FIG. 4 is a chart showing the relationship between surface resistance and percentage of sulfonic acid groups with the remainder of sulfonate groups having both lithium and sodium as counter ions.

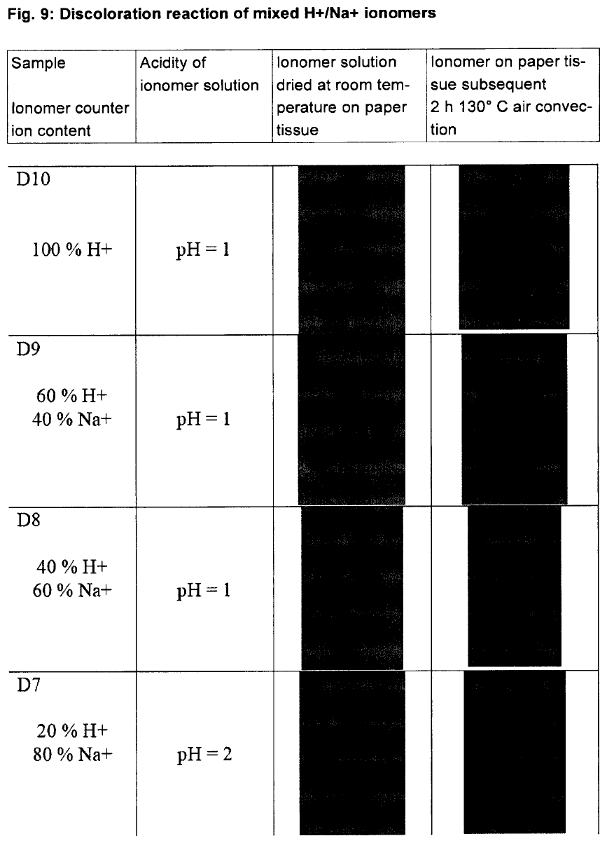

FIG. 2 is a chart showing the relationship between surface resistance and percentage of sulfonic acid groups with the remainder of sulfonate groups having both lithium and magnesium as counter ions.

FIG. 6 is a chart summarizing results for all coatings shown in FIGS. 2 to 5 as well as additional coatings.

FIG. 7 shows the relationship between surface resistance and coating weight per area for ePTFE membranes coated with Flemion FSS-2 ionomers having different counter ions.

FIG. 8 shows discoloration for different ionomer solutions used to prepare coatings as shown in FIG. 2.

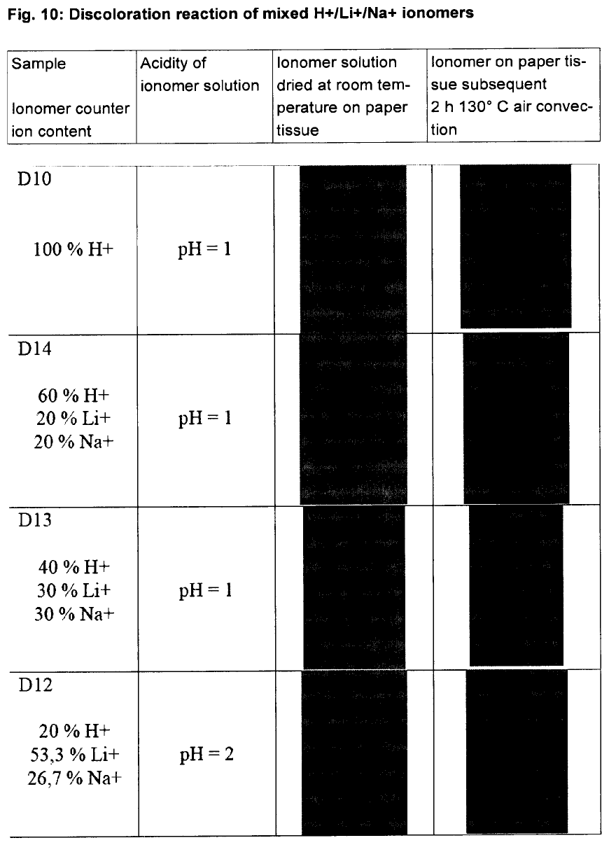

FIG. 9 shows discoloration for different ionomer solutions used to prepare coatings as shown in FIG. 3.

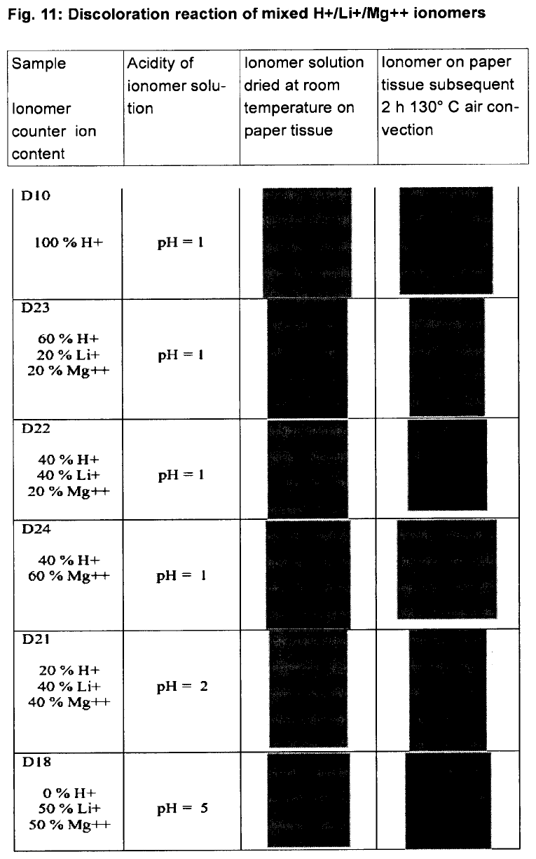

FIG. 10 shows discoloration for different ionomer solutions used to prepare coatings as shown in FIG. 4.

FIG. 11 shows discoloration for different ionomer solutions used to prepare coatings as shown in FIG. 5.

### DETAILED DESCRIPTION

It is an object of the present invention to provide coating materials suitable for forming ESD (electrostatic dissipative) coatings having at least some of the following properties:
High surface conductivity,
Low charge build up under flexing conditions,
Low particulation under flexing conditions,
Low discoloration caused by chemical interactions,
Low material transfer to lamination equipment in a lamination procedure,
Efficient wetting of substrates having low surface energy such as fluoropolymers, for example PTFE,
Resistance against cleaning fluids, and
Compatibility with environmental regulations.

Desirably, the coating materials should have well balanced properties in all respects.

The object is achieved by the inventive coating composition comprising an ionomer having a polymer backbone and side chains comprising ionic groups in the acid form and in the salt form, wherein the ionic groups in the acid form and in the salt form are sulfonic acid groups and sulfonate groups, from 50 to 95% of the total number of sulfonic acid groups and sulfonate groups are in the sulfonate form, and the sulfonate groups have counter ions M selected from the group consisting of lithium, sodium, magnesium, calcium and mixtures thereof.

Subject-matter of the invention is also an article comprising a porous or non-porous polymeric substrate and a coating thereon, wherein the coating is formed from the inventive coating composition. The coating is non-fragmented, i.e. visual inspection does not reveal individual particles.

In an embodiment the article is a flexible sheet or tape, the sheet or the tape comprising an electrically insulating substrate having the antistatic coating of the invention on a surface thereof. The sheet or tape is suitable as a cable cover of cables which are subjected to repeated extensive flexing and bending such as cable connections in semiconductor processing.

Subject-matter of the invention is also a cable comprising an outermost electrically insulating layer and a coating thereon, the coating being formed from the inventive coating composition.

Subject-matter of the invention is further the use of an ionomer having a polymer backbone and side chains comprising ionic groups in the acid form and in the salt form, wherein
the ionic groups in the acid form and in the salt form are sulfonic acid groups and sulfonate groups,
from to 50% to 95% of the total number of sulfonic acid groups and sulfonate groups are in the sulfonate form, and
the sulfonate groups have counter ions M selected from the group consisting of lithium, sodium, magnesium, calcium, and mixtures thereof, for forming an antistatic (ESD, electrostatic dissipative) coating on an electrically non-conductive substrate.

For the purpose of the present invention, a substrate is regarded as non-conductive or electrically insulating, respectively, when the surface resistance is higher than 10¹¹ Ohm/square at 23° C. and 50% relative humidity measured with an inch² sized electrode at 100 V DC.

After coating with the inventive coating composition, the surface resistance is reduced to a value below 10¹⁰ Ohm/square, preferably to a value below 10⁹ Ohm/square, more preferably to a value of 10⁸ Ohm/square or below, and particularly preferably to a value of 10⁷ Ohm/square or below, measured at 23° C. and 50% relative humidity with an inch² sized electrode at 100 V DC.

In one embodiment of the use of the present invention, the surface resistance of the uncoated substrate is reduced by the antistatic coating by a factor of at least 10², in a further embodiment by a factor of at least 10³, in yet another embodiment by a factor of at least 10⁴. For example, the surface resistance of PTFE usually is >10¹² Ohm/square and may be reduced by the use of the antistatic coating to values of 10⁷ Ohm/square or even below corresponding to a factor of 10⁵ or even higher. Coating amounts influence the surface resistance reduction which can be achieved. Generally, higher coating weights provide lower surface resistance.

Substrates for use in the present invention are not particularly limited, and any organic or inorganic material, such as synthetic and/or natural polymers, and composites of synthetic and/or natural polymers may be used.

Exemplary substrates are fluoropolymers, i.e. polymers which contain fluorine atoms, wherein the fluoropolymer may be partially fluorinated, perfluorinated or fully fluorinated. Especially fully fluorinated substrates are known to be difficult to coat.

A particularly preferred substrate comprises, or consists of, polytetrafluoroethylene (PTFE), or a tetrafluoroethylene copolymer, comprising, in addition to tetrafluoroethylene monomer units, further perfluorinated, partially fluorinated or non-fluorinated co-monomer units.

The substrate may be porous or microporous or non-porous. A porous substrate has voids throughout the internal structure which form an interconnected continuous air path from one surface to the other. Preferred substrates are porous substrates. In such substrates the average pore size is in the range of 0.1 to 50 micrometers (largest pore diameter), as determined by scanning electron microscopy, preferably in the range of from 0.5 to 25 micrometers.

The substrate can be in the form of a tape, tube, fiber, sheet or membrane. The thickness of the substrate is not particularly limited, and exemplary thicknesses range from about 1 μm to 10 mm, or from 10 μm to 5 mm, or from 0.1 to 1.0 mm.

In an embodiment, the substrate comprises or consists of a porous or microporous membrane of expanded PTFE.

The coating composition applied to the substrate in order to minimize electric charge build up comprises a particular ionomer. Preferred ionomers are organic polymers having a polymer backbone and side chains comprising sulfonic acid and sulfonate ionic groups. The total number of ionic groups of an ionomer corresponds to the total number of sulfonic acid and sulfonate groups.

Generally, most ionomers may be regarded as co-polymers formed from moieties having ionic groups, and moieties without such groups. The ionic groups are typically carboxylic acid groups, phosphoric acid groups or sulfonic acid groups, or carboxylate groups, phosphate groups and sulfonate groups, respectively.

The ionomers useful for the purpose of the present invention have sulfonic acid groups and sulfonate groups as the sole ionic groups. The ionic groups are present on side chains, whereas no ionic groups exist on the polymer backbone. Ionomers having sulfonic acid groups are readily available on the market (e.g. Nafion®, Flemion®) or can be prepared by co-polymerizing appropriate monomer units in the desired relative amounts.

The fully protonated ionomers, i.e. the ionomers having sulfonic acid groups can be easily converted into ionomers having the corresponding sulfonate salt groups by contacting the protonated ionomers with an appropriate amount of a salt of a volatile weak acid or with a hydroxide of the desired counter ion, e.g. with LiOH or NaOH. For example, an ionomer in the fully protonated form can be dissolved or dispersed in a solvent or dispersing medium such as alcohol or an alcohol/water mixture, and a salt of a volatile weak organic acid may be added. The sulfonic acid groups react with the added acid salts which leads to the release of the respective volatile organic acid, thereby forming an ionomer with sulfonate salt groups. In order to achieve a quantitative reaction, it is preferred to finally heat the reaction mixture to an appropriate temperature to drive off the volatile weak organic acid. The reaction is typically completed after complete drying of the coating layer. Since the reaction proceeds quantitatively, the ratio auf sulfonic acid groups which will be converted into sulfonate salt groups can be predetermined by adding the required stoichiometric amount of a weak acid salt or a mixture of weak acid salts. Mixtures of weak acid salts having the same anion, but different cations, yield ionomers having sulfonate salt groups with cations in the same ratio as in the weak acid salt mixture. This applies analogously to salt formation with hydroxides. Sulfonate salt formation with a hydroxide of a desired cation proceeds quantitatively without heating the reaction mixture.

In order to achieve the object of this invention, in particular high electrostatic discharge performance of the antistatic coating in combination with a low tendency to corrode and/or discolor materials contacting the antistatic coating, it is essential that a combination of conditions is fulfilled. A first condition is that the ionic groups of the ionomer are sulfonic acid groups and sulfonate groups. A second condition is that the sulfonic acid groups and sulfonate groups are present in a specific ratio. A third condition is that the sulfonate groups have the appropriate counter ions. There are further properties of the ionomer, which are not mandatory, but advantageous. Such properties are a particular equivalent weight of the ionomer, and a particular side chain length. The equivalent weight of the ionomer is the weight of the polymer in grams which corresponds to 1 mol ionic groups, i.e. sulfonic acid groups and sulfonate groups in combination.

In the ionomers for the use of the present invention, i.e. for forming an antistatic coating on an electrically non-conductive substrate, from 50% to 95% of the total number of sulfonic acid groups and sulfonate groups are in the sulfonate form. Preferably, from 50% to 80% of the total number of sulfonic acid groups and sulfonate groups are in the sulfonate form, and particularly preferably, from 60% to 80% of the total number of sulfonic acid groups and sulfonate groups are in the sulfonate form. These ratio ranges have been found to provide an optimum balance between the desired surface resistivity and corrosion/discoloration properties.

Further, in order to achieve optimum balance between the desired surface resistance and corrosion/discoloration properties, the counter ions of the sulfonate groups must be appropriately selected. In the present invention, the counter ions are lithium, sodium, magnesium, calcium, or any mixture thereof. Preferably, the counter ion is lithium, or a combination of lithium and sodium, or a combination of lithium and magnesium. Also sodium performs particularly well. These counter ions and combinations of counter ions, respectively, are not only advantageous in terms of surface resistance and corrosion/discoloration properties, but also provide for enhanced mechanical properties of the resulting antistatic coating, such as reduced embrittlement and, therefore, low particulation during bending and flexing of a coated article. They also provide for enhanced resistance of the ionomer coating against cleaning fluids. Li counter ions, in particular, provide for enhanced embrittlement behavior, and Na counter ions provide for particularly good resistance to cleaning fluids, probably due to swelling resistance of sodium ions containing ionomer coatings.

lonomers for use of this invention are “fluoroionomers”. The term designates ionomers which are partially fluorinated or perfluorinated. Preferably, the fluoroionomers are copolymers of F₂C=CF₂ (tetrafluoroethylene) and perfluorinated vinyl ethers. The ionomers may contain additional building blocks derived from fluorinated olefins as e.g., perfluoro-alkoxy monomers of different chain length or hexafluoropropylene. Further, partially fluorinated olefins, such as H₂C=CHF (vinyl fluoride), H₂C=CF₂ (VDF; vinylidene fluoride), HFC=CHF, and chlorine containing momeners such as ClFC=CF₂ (chlorotrifluoroethylene), respectively, may be considered.

lonomers having a high fluorine content, in particular perfluorinated ionomers are preferable for coating perfluorinated substrates such as PTFE substrates. The enhanced compatibility of substrates and coating promotes coating film formation, thus reliably avoiding coating particulation.

Importantly, in the fluoroionomers of this invention, any ether moieties are in the side chains, i.e. the fluoroionomers do not constitute fluoropolyethers. Fluoro polyethers known under the term perfluoropolyethers (PFPE) have a tendency to bloom and migrate on surfaces, which is very disadvantageous in many applications, e.g. in clean rooms.

Polymers with ionic groups in the main chain show strong intermolecular attractive interactions which leads to a significant reduction of the molecular mobility of the main chain, chain stiffness and finally brittleness of the material. Furthermore due to the minimal chain mobility and stiffness of polar main chain polymers they tend to form inconsistent coatings with low adherence to perfluorinated substrates.

In the contrary, the fluorinated ionomer used for the purpose of ESD protection consists of a polymer backbone which is linked by an ether group to side chains which carry ionic groups. Due to the polymer side chain architecture the ionic groups are decoupled from the main chain and therefore the ionic interactions present are less restrictive to the main chain mobility.

As regards the equivalent weight (EW) of the ionomer, a low equivalent weight is preferable under the aspect of high conductivity. On the other hand, polar interactions increase with decreasing equivalent weight, leading to loss of toughness, which may cause particulation of the coating under severe flexing and bending conditions. An equivalent weight from about 700g/mol to about 1300 g/mol is preferable, and an equivalent weight from about 800 g/mol to about 1200 g/mol is particularly preferable.

Particularly preferred ionomers have repeating units of the following formula

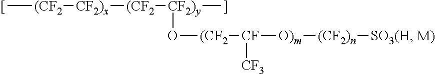

wherein
x is in a range from 1 to 14,
y=1,
m is in a range from 0 to 3,
n is in a range from 1 to 5, and
(H, M) means that either a sulfonic acid group or a surfonate group with a counter ion M may be present.

The molecular weight of such polymers is e.g., in a range of from 10⁴ to 10⁷ Da or from 10⁵ to 10⁶ Da, however, other molecular weights are also suitable.

Commercially available fluoroionomers falling under the above formula are, for example, Nafion, Flemion, Aquivion, and Aciplex. Most of the commercially available fluoroionomers are in the fully protonated forms.

Generally, longer side chains (m+n≥3) are preferable under the aspect of enhanced resistance against particulation of the coating under flexing and bending conditions.

The antistatic coating of this invention consists of the ionomer or comprises the ionomer, i.e. the coating may contain further constituents in addition to the ionomer. For example, non-ionomeric organic polymers may be blended with the ionomers, such as non-ionic thermoplastic resins. In addition, conventional additives used in polymeric materials may be included, for example plasticizers, humectants, stabilizers, antiblock agents, etc. Such additives, however, should not be in particulate form. The antistatic coating composition of this invention preferably is either a solution which does not contain any particles or a dispersion which does not contain particles different from the ionomer particles. Generally, additives may be contained in the coating composition in an amount of more than 0 weight % and up to about 20 weight % of the composition, but preferably the antistatic coating composition of this invention consists of the ionomer described above.

Likewise, the coating composition preferably does not contain any compounds capable of forming complexes with the counter ions of the sulfonate groups of the ionomer (a complex being a compound with dative bonds, both binding electrons being delivered by the compound to interact with an unoccupied state of a respective cation), or which may migrate on surfaces, thus potentially leading to contamination, for example polyether compounds.

Antistatic coatings of this invention may be produced by applying the coating composition of this invention, the composition comprising the ionomer in liquid form onto a substrate. The coating composition can be a liquid as such, but typically it is brought in the liquid form by dissolving or dispersing the coating composition in a solvent or dispersing agent, respectively. The solvent or the dispersing agent is not particularly limited, and any medium or mixed medium can be used which appropriately dissolves or disperses the coating composition, and which can be removed after coating at a reasonably low temperature, i.e. at a temperature which does not deteriorate the substrate or the coating. Water, lower alcohols, and mixtures thereof are preferable.

It should be noted that, while the composition may be applied onto a substrate in the form of a dispersion, the final coating is nevertheless non-fragmented, i.e. after drying no individual particles can be discriminated. Rather, the particles appear to merge, yielding a coating in the form of a film, irrespective of whether a solution or a dispersion was used for applying the coating

The coated film may be virtually closed, covering the substrate homogenously, or it may be macro-porous. A preferred embodiment of this invention is a porous coating layer on a porous substrate.

The observed surface morphology correlates with the amount of applied coating: At low weight per area (wpa) discontinuous films are formed, while at higher wpa (e.g., 10-12 g/m²; samples D7-D24 described later) continuous films are formed.

Any application techniques known to a skilled person for applying liquid compositions to substrates are suitable for coating substrates with the coating composition of this invention or for imbibing the composition into pores of the substrate. The substrates may have any geometrical shape, but typically the substrates are in sheet form or tape form, thus having two opposing main surfaces. The inventive coating composition may be applied to only one of the surfaces or to both surfaces of the substrate, and it may cover the complete surface or only portions thereof. In embodiments the coating composition covers the whole surface area. A cable may be prepared by applying a coating on a cable jacket made from e.g., ePTFE covering a wire/conductor/conduit configuration. An insulated wire may be prepared by applying a coating on e.g., an ePTFE insulation on a conductor (primary insulation).

Coating amounts can be tailored to needs. Exemplary amounts range from about 0.1 g/m² to 20 g/m², or from about 1g/m² to about 15 g/m² or from about 2 g/m² to about 10 g/m² (dry weight). Higher coating weights provide for higher conductivity but at coating weights exceeding about 10 g/m² conductivity increase levels off. On the other hand, high coating weights bear the risk of particulation during flexing and bending. Therefore coating weights (dry weight) below 10 g/m² are preferable, and coating weights below 5 g/m² are particularly preferable.

In the case of porous substrates, for example in the case of membranes made from expanded polytetrafluorethylene, the coating may be applied to the surfaces of the pores of the substrate, covering the inner surfaces of the pores, but without sealing the pores. In another embodiment, the pores may be completely filled. Of course, the coating composition may be present both within the pores of a substrate and on one or two surfaces of the substrate. It is also possible, to provide the antistatic coating of this invention as a layer (inner layer) between two substrate layers (outer layers).

The present invention focuses, in particular, on cables and cable assemblies suitable for use in semiconductor manufacturing and testing procedures. In such procedures electric charge build up and coating material particulation are promoted due to the extensive flexing of the cable connections, and are particularly disadvantageous due to the dramatic effects of electric charge build up and particulation in the semiconductor field.

In an embodiment, the present invention provides cable covers and cable jackets which do not suffer from the disadvantages of prior art cable covers and cable jackets.

A cable cover in the sense of this invention is a sheet or tape comprising a substrate as described above, the substrate having an antistatic coating according to this invention on one surface thereof. An adhesive layer may be provided on the opposite surface thereof. The substrate is preferably made from expanded PTFE. The adhesive is not particularly limited, and may be any adhesive suitable for combining two cable covers. Hot melt adhesives are preferred, and particularly preferred are adhesive based on polyurethane.

A cable jacket in the sense of this invention is formed by laminating two cable covers. For example, a conductor or conduit is placed between two cable covers, the antistatic coatings facing away from the conductor or conduit. One or both of the cable covers may be coated with an appropriate adhesive at the surface facing towards the conductor or conduit. Alternatively, or in addition, a channel may be formed within a cable jacket by placing a removable form between two cable covers and laminating the cable covers together with an appropriate adhesive. Then, the removable form is removed, leaving a channel within the cable jacket. The conductor(s) and/or conduit(s) and/or channel(s) enclosed within a jacket constitute a cable according to this invention.

As understood herein, conductors are substances or media that permit electricity, light, heat, or other forms of energy to pass through them. Conduits are pathways for conveying energy, fluids, or gases. Channels are hollow tubes or ducts for transferring gases or liquids. Alternatively, channels can also house conductors and/or conduits and/or any other members. Conductors for electricity are e.g., metal wires.

A cable jacket may not only enclose one single conductor (e.g., electrically conducting wire or different conductor) or conduit or channel, but rather any number of conductors and/or conduits and/or channels appropriate for a particular purpose, thus forming a cable assembly.

Alternatively, a cable or cable assembly according to this invention can be fabricated by providing an electrically conductive wire or other conductor, or by providing an arrangement comprising at least one conductor and/or at least one conduit and/or at least one channel with an outermost electrically non-conductive layer (e.g., ePTFE), and then coating the insulated arrangement with the inventive coating composition.

In the following, the invention is further illustrated by working examples.

### EXAMPLE 1

### Preparation of Coating Formulations Comprising Inventive Coating Compositions

An ionomer solution selected from the materials described in table 1 is stirred by the use of a magnetic stirrer at a rate of 600 revolutions per minute. The solution is kept under constant stirring during the next preparation steps.

Subsequently a specific amount of water as depicted in table 2 is added over a time frame of 1 minute. The solution is stirred for additional 10 minutes without any additional treatment. In a subsequent step a specific amount of a neutralization agent or neutralization agent mixture as depicted in table 2 is added over a time frame of 30 s. The mixture is ready to be used for coating purposes after an additional stirring period of 5 h in a closed container. During this time period the neutralization agent dissolves slowly and reacts with the sulfonic acid ionomer to form the respective salt forms. After completion of the described process steps the coating solution should be free from any neutralization agent precipitate or polymer gel content.

TABLE 1
Fluorinated Ionomers

| Trade name | Manufacturer | Composition |
|---|---|---|
| Flemion FSS-2 | Asahi Glas | 9-11 wt % solution |
| | | in ethanol |
| Nation D2020 | Chemours | 20-22 wt % solution |
| | | 34% water, |
| | | 46% lower aliphatic alcohols |
| Aquivion D72-25BS | Solvay | 25 wt % solution |
| | | in water |

TABLE 2
Formulations based on Flemion FSS-2

| | | | Formulation | | | | | | | | | |
|---|---|---|---|---|---|---|---|---|---|---|---|---|
| | | | | | | | | | | | Stoi- | |
| | | | | | | | | | | | chiometry | |
| | | | | | | | | | Weight | Valence | (Degree | |
| Target Ionomer | | | Solution | Solution | | Equivalent | Neutral- | Molecular | Neutral- | Factor | of | |
| | Proton | Metal | weight | conc. | Ionomer | weight | ization | weight | ization | Counter- | neutral- | Weight |
| Sample | Content | Counterion | Ionomer | Ionomer | content | Ionomer | agent | of agent | agent | ion | ization) | Water |
| | | Na+ | 20 | 10 | 2 | 909 | NaAcetate | 82.03 | 0.1444 | 1 | 0.8 | 4 |
| D 7 | 20 | | | | | | | | | | | |
| | | Na+ | 20 | 10 | 2 | 909 | NaAcetate | 82.03 | 0.1083 | 1 | 0.6 | 4 |
| D 8 | 40 | | | | | | | | | | | |
| | | Na+ | 20 | 10 | 2 | 909 | NaAcetate | 82.03 | 0.0722 | 1 | 0.4 | 4 |
| D 9 | 60 | | | | | | | | | | | |
| | | | 20 | 10 | 2 | 909 | non | | | | 0 | 4 |
| D 10 | 100 | | | | | | | | | | | |
| | | Li+ | 20 | 10 | 0.667 | 909 | LiAceta- | 102.02 | 0.0599 | 1 | 0.8 | 4 |
| | | | | | | | tex2H2O | | | | | |
| D 11 | 20 | Na+ | | | 1.333 | 909 | NaAcetate | 82.03 | 0.0962 | 1 | 0.8 | |
| | | Li+ | 20 | 10 | 1.333 | 909 | LiAceta- | 102.02 | 0.1197 | 1 | 0.8 | 4 |
| | | | | | | | tex2H2O | | | | | |
| D 12 | 20 | Na+ | | | 0.667 | 909 | NaAcetate | 82.03 | 0.0482 | 1 | 0.8 | |
| | | Li+ | 20 | 10 | 1 | 909 | LiAceta- | 102.02 | 0.0673 | 1 | 0.6 | 4 |
| | | | | | | | tex2H2O | | | | | |
| D 13 | 40 | Na+ | | | 1 | 909 | NaAcetate | 82.03 | 0.0541 | 1 | 0.6 | |
| | | Li+ | 20 | 10 | 1 | 909 | LiAceta- | 102.02 | 0.0449 | 1 | 0.4 | 4 |
| | | | | | | | tex2H2O | | | | | |
| D 14 | 60 | Na+ | | | 1 | 909 | NaAcetate | 82.03 | 0.0361 | 1 | 0.4 | |
| | | Li+ | 20 | 10 | 2 | 909 | LiAceta- | 102.02 | 0.0898 | 1 | 0.4 | 4 |
| | | | | | | | tex2H2O | | | | | |
| D 15 | 60 | H+ | | | | | | | | | | |
| | | Li+ | 20 | 10 | 2 | 909 | LiAceta- | 102.02 | 0.1347 | 1 | 0.6 | 4 |
| | | | | | | | tex2H2O | | | | | |
| D 16 | 40 | | | | | | | | | | | |
| D 17 | 20 | Li+ | 20 | 10 | 2 | 909 | LiAceta- | 102.02 | 0.1796 | 1 | 0.8 | 4 |
| | | | | | | | tex2H2O | | | | | |
| | | Li+ | 20 | 10 | 1 | 909 | LiAceta- | 102.02 | 0.1207 | 1 | 1.075 | 4 |
| | | | | | | | tex2H2O | | | | | |
| D18 | 0 | Mg++ | | | 1 | 909 | MgAceta- | 214.45 | 0.1268 | 2 | 1.075 | |
| | | | | | | | tex4H2O | | | | | |
| D19 | 0 | Mg++ | 20 | 10 | 2 | 909 | MgAceta- | 214.45 | 0.2536 | 2 | 1.075 | 4 |
| | | | | | | | tex4H2O | | | | | |
| | | Li+ | 20 | 10 | 1.5 | 909 | LiAceta- | 102.02 | 0.1347 | 1 | 0.8 | 4 |
| | | | | | | | tex2H2O | | | | | |
| D 20 | 20 | Mg++ | | | 0.5 | 909 | MgAceta- | 214.45 | 0.0472 | 2 | 0.8 | |
| | | | | | | | tex4H2O | | | | | |
| | | Li+ | 20 | 10 | 1 | 909 | LiAceta- | 102.02 | 0.0898 | 1 | 0.8 | 4 |
| | | | | | | | tex2H2O | | | | | |
| D 21 | 20 | Mg++ | | | 1 | 909 | MgAceta- | 214.45 | 0.0944 | 2 | 0.0944 | 2 |
| | | | | | | | tex4H2O | | | | | |
| | | Li+ | 20 | 10 | 1.333 | 909 | LiAceta- | 102.02 | 0.0898 | 1 | 0.6 | 4 |
| | | | | | | | tex2H2O | | | | | |
| D 22 | 40 | Mg++ | | | 0.667 | 909 | MgAceta- | 214.45 | 0.0472 | 2 | 0.6 | |
| | | | | | | | tex4H2O | | | | | |
| | | Li+ | 20 | 10 | 1 | 909 | LiAceta- | 102.02 | 0.0449 | 1 | 0.4 | 4 |
| | | | | | | | tex2H2O | | | | | |
| D 23 | 60 | Mg++ | | | 1 | 909 | MgAceta- | 214.45 | 0.0472 | 2 | 0.4 | |
| | | | | | | | tex4H2O | | | | | |
| D 24 | 40 | Mg++ | 20 | 10 | 2 | 909 | MgAceta- | 214.45 | 0.1416 | 2 | 0.6 | 4 |
| | | | | | | | tex4H2O | | | | | |
| ESD 15 | 2 | Li+ | 20 | 10 | 2 | 909 | LiAceta- | 102.02 | 0.2193 | 1 | 0.98 | 4 |
| | | | | | | | tex2H2O | | | | | |
| ESD 25 | 2 | Na+ | 20 | 10 | 2 | 909 | NaAcetate | 82.03 | 0.1769 | 1 | 0.98 | 4 |
| | | Ca++ | | | 1 | 909 | CaAcetatex- | 158.17 | 0.0850 | 2 | 0.98 | |
| | | | | | | | H2O | | | | | |
| ESD 23 | 2 | Li+ | 20 | 10 | 1 | 909 | LiAceta- | 102.02 | 0.1097 | 1 | 0.98 | 6 |
| | | | | | | | tex2H2O | | | | | |
| | (%) | | w (g) | w % | w (g) | Mw (g/mol) | | Mw (g/mol) | w (g) | | | w (g) |

### Explanation of Table 2

Sample D10 contained Flemion FSS-2 in the fully protonated form, while samples D18 and D19 contained Flemion FSS-2 in salt form, i.e. without sulfonic acid groups. Samples ESD 15, ESD 23, and ESD 25 each contained 2% of the ionic groups in the sulfonic acid form. Therefore, samples D10, D18, D19, ESD 15, ESD 23, and ESD 25 are comparative samples, while the remaining samples are samples according to this invention.

In the column “stoichiometry” the degree of neutralization is indicated. Some samples, for example samples D11 and D12, contain two different counter ions. In such cases the total degree of neutralization is indicated, and the ratio of the counter ions can be seen in the column “ionomer content”.

### EXAMPLE 2

### Preparation of Coated Cable Cover

Coating solutions prepared according to the procedures described in Example 1. Preparations of formulations had been coated on a Gore composite membrane part no. 10131349-WH (made from ePTFE membrane 10346174) by the use of a Wet Film Applicator Rod (wire wound applicator) made from of a 5 mm steel rod and wound 500 micrometer diameter wire.

For this purpose approximately 0.5 g of the respective solution is applied on the ePTFE membrane surface (piece of 6.0×11 cm in rectangular shape). Subsequent to the first coating procedure the coated specimen was dried for 5 min at 110° C. in a forced air convection oven. Note that in the coating solutions obtained in Example 1 the reaction participants are present in an equilibrium. The reaction is completed, and the target degree of neutralization achieved, by removing the weak acid from the equilibrium. Supporting the removal by heating is preferable in order to speed up the process.

The coating and drying procedures were repeated up to 4 times in order to generate specimen with systematically varying coating weight per area. By means of this subsequent process a broad range of coated ePTFE composite membranes had been prepared which are described in table 3. Each assignment given contains information about the coating solution used and the number of subsequent coating runs.

For example, sample D 10 4 is made from coating solution D 10 according to table 2, and had been coated and dried 4 times. D 10 4 is coated with 0.001170 g ionomer per square centimeter (11. 7 g/m²).

TABLE 3
Coated composite membranes and their
coating weight per area (wpa)

| Coating 1 | Coating 2 | Coating 4 | |
|---|---|---|---|
| D 7 1 | D 7 2 | D 7 4 | |
| 0.000203172 | 0.000474143 | 0.001040208 | Coating wpa |
| | | | (g/cm2) |
| D 8 1 | D 8 2 | D 8 4 | |
| 0.000224189 | 0.000488626 | 0.00107861 | |
| D 9 1 | D 9 2 | D 9 4 | |
| 0.000215856 | 0.00052086 | 0.001065049 | |
| D 10 1 | D 10 2 | D 10 4 | |
| 0.000277277 | 0.000544377 | 0.00116991 | |
| D 11 1 | D 11 2 | D 11 4 | |
| 0.000258221 | 0.000570761 | 0.001147378 | |
| D 12 1 | D 12 2 | D 12 4 | |
| 0.000305281 | 0.000584498 | 0.001069266 | |
| D 13 1 | D 13 2 | D 13 4 | |
| 0.000262479 | 0.000512281 | 0.001102956 | |
| D 14 1 | D 14 2 | D 14 4 | |
| 0.000228575 | 0.000519893 | 0.001062184 | |
| D 15 1 | D 15 2 | D 15 4 | |
| 0.000254392 | 0.000581662 | 0.001114562 | |
| D 16 1 | D 16 2 | D 16 4 | |
| 0.00027332 | 0.000588471 | 0.00105552 | |
| D 17 1 | D 17 2 | D 17 4 | |
| 0.000276743 | 0.00055194 | 0.001085872 | |
| D 18 1 | D 18 2 | D 18 4 | |
| 0.000252231 | 0.000551926 | 0.001042748 | |
| D 20 1 | D 20 2 | D 20 4 | |
| 0.000222722 | 0.000579988 | 0.001048266 | |
| D 21 1 | D 21 2 | D 21 4 | |
| 0.000252061 | 0.000500246 | 0.001062138 | |
| D 22 1 | D 22 2 | D 22 4 | |
| 0.000225999 | 0.000538138 | 0.001135215 | |
| D 23 1 | D 23 2 | D 23 4 | |
| 0.000234281 | 0.000566128 | 0.001111635 | |
| D 24 1 | D 24 2 | D 24 4 | |
| 0.000218511 | 0.000511475 | 0.001098411 | |

| Coating 1 | Coating 2 | Coating 3 | Coating 4 | Coating 5 |
|---|---|---|---|---|
| ESD 15 1 | ESD 15 2 | ESD 15 3 | ESD 15 4 | ESD 15 5 |
| 0.00025 | 0.00055 | 0.0008 | 0.001200 | 0.00135 |
| ESD 25 1 | ESD 25 2 | ESD 25 3 | ESD 25 4 | ESD 25 5 |
| 0.000145 | 0.000430 | 0.00065 | 0.000820 | 0.001170 |
| ESD 23 1 | ESD 23 2 | ESD 23 3 | ESD 23 4 | ESD 23 5 |
| 0.000203 | 0.000467 | 0.000764 | 0.001061 | 0.001240 |

### EXAMPLE 3

### Measurement of Surface Resistance

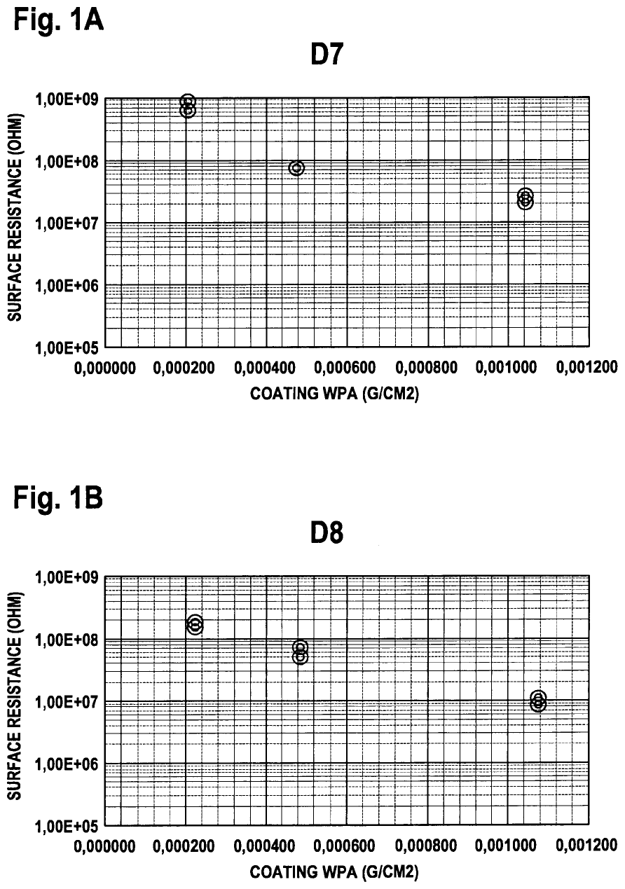

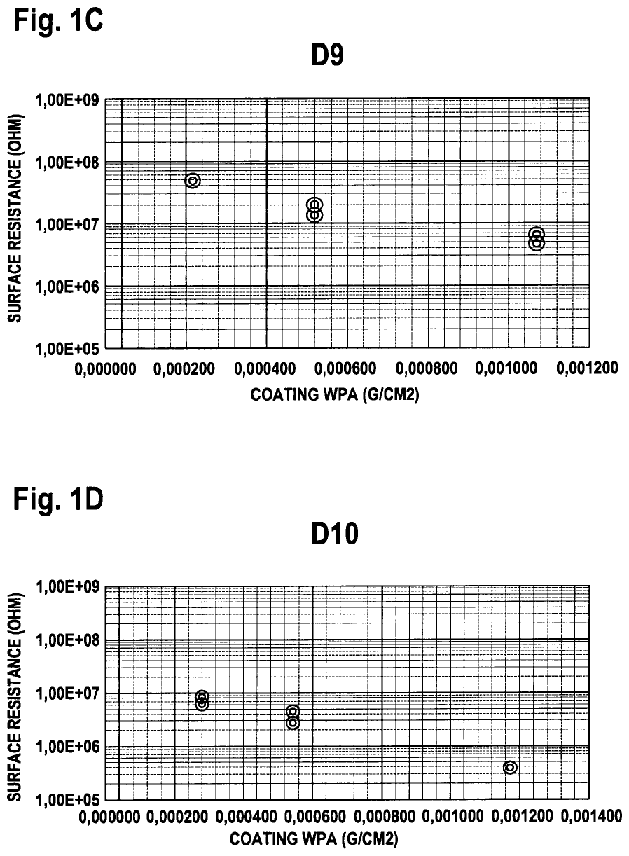

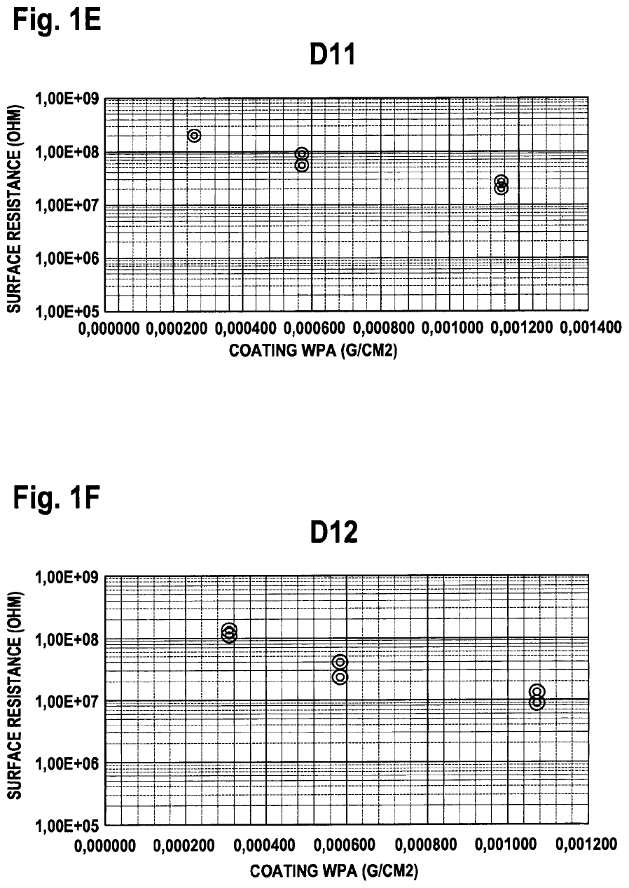

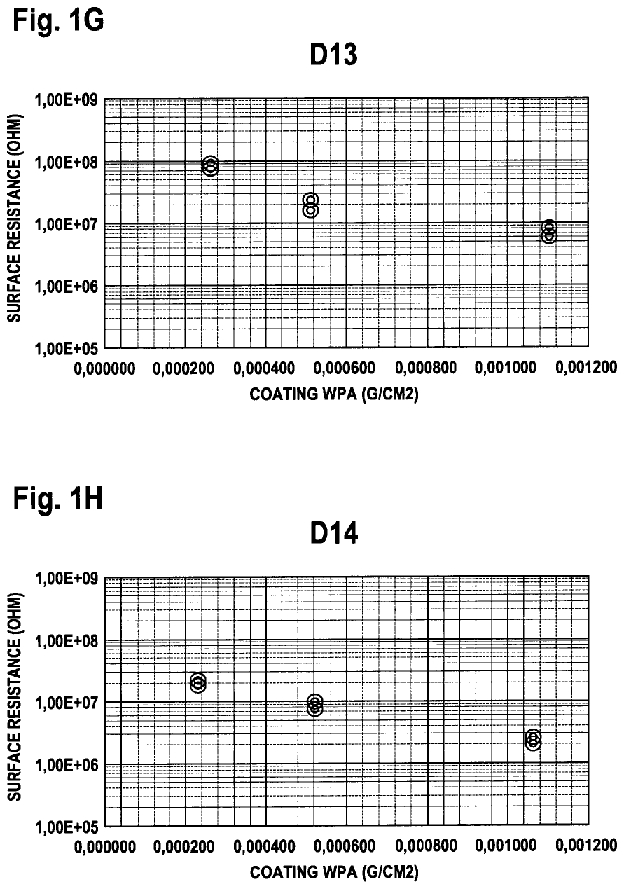

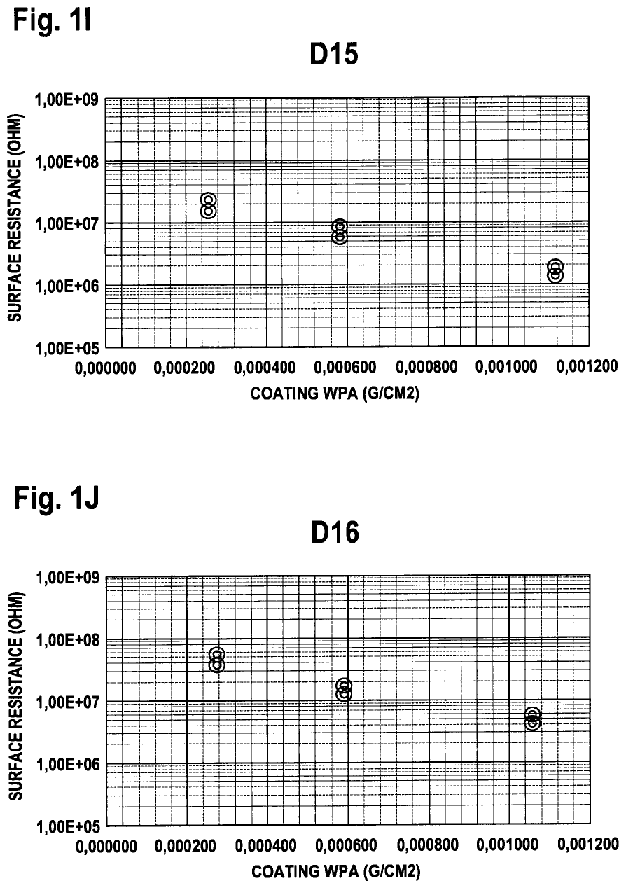

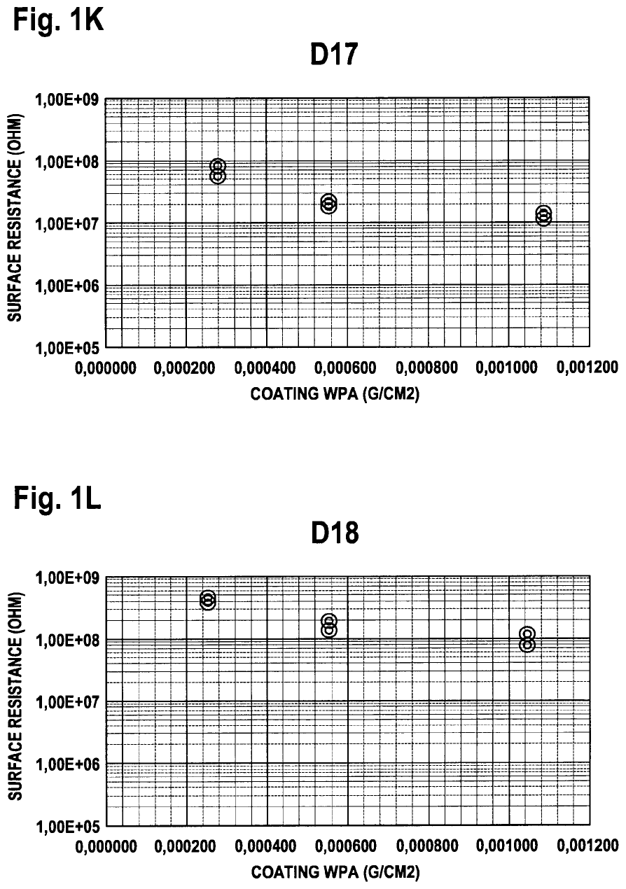

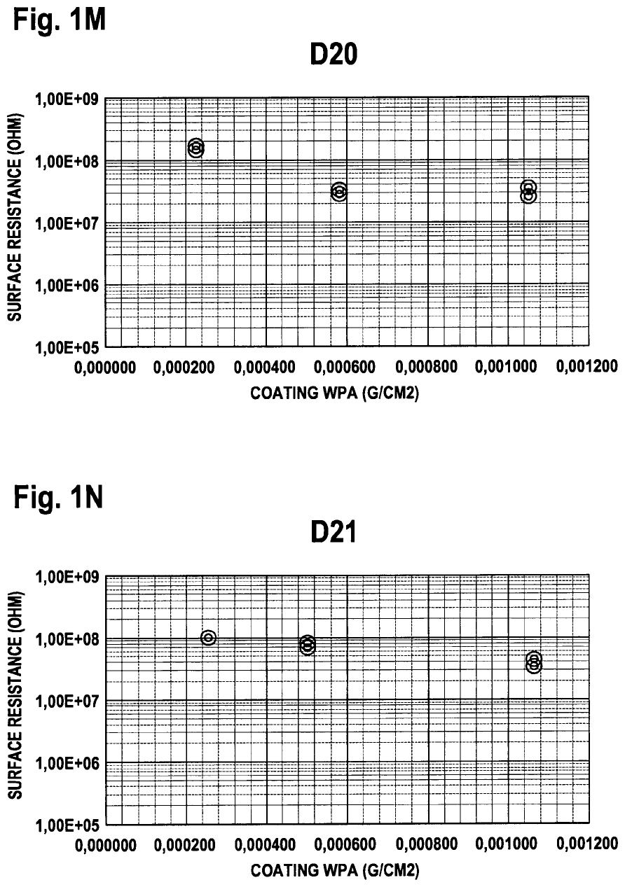

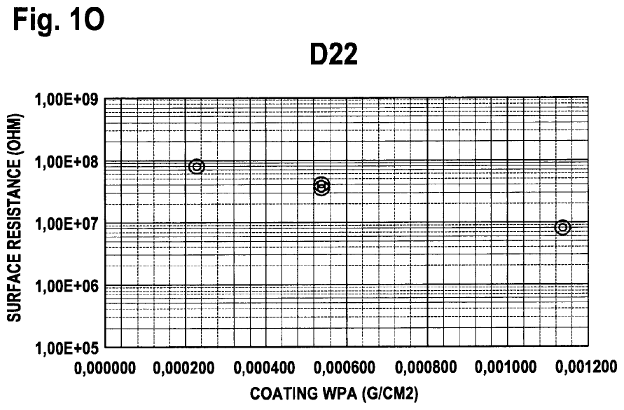

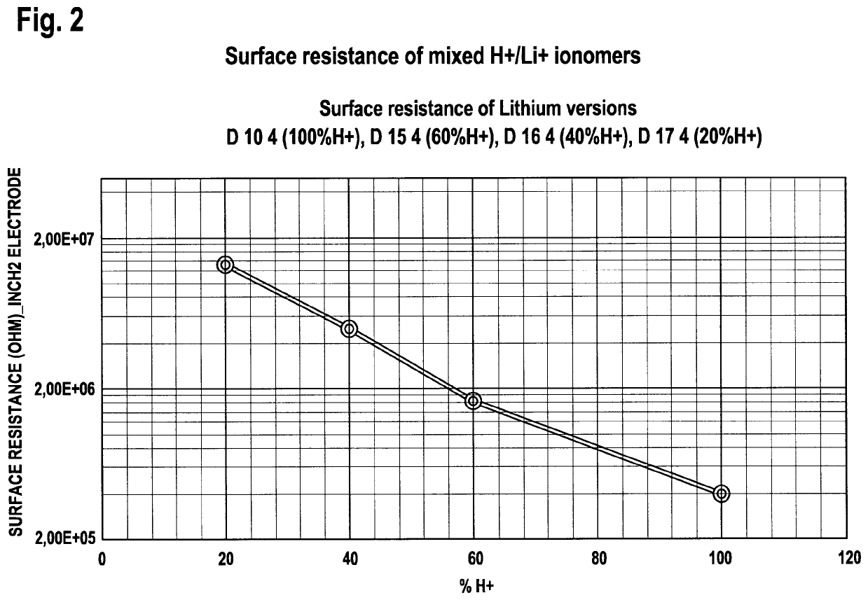

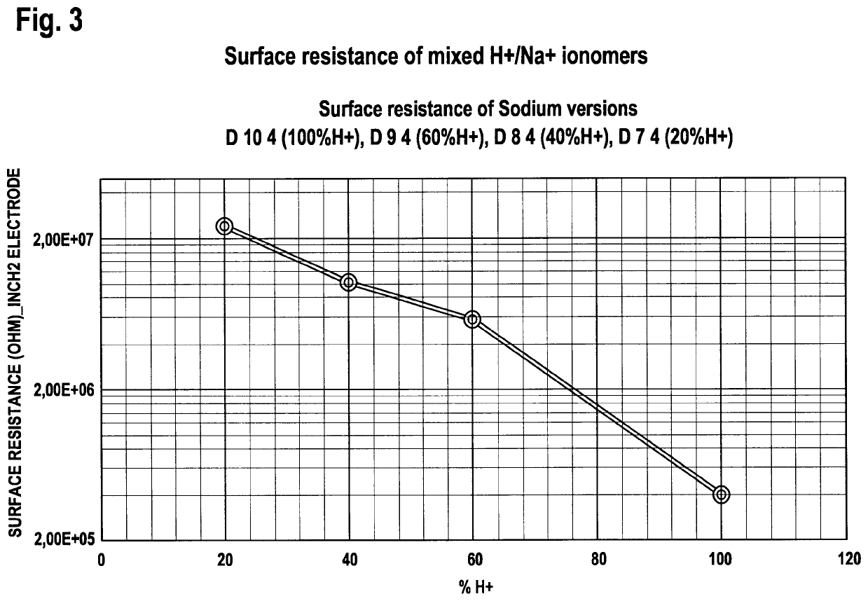

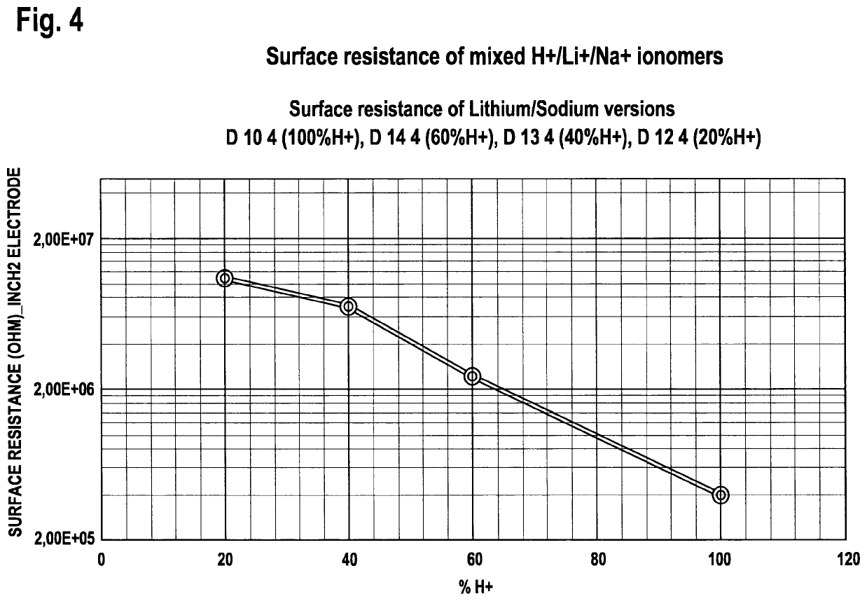

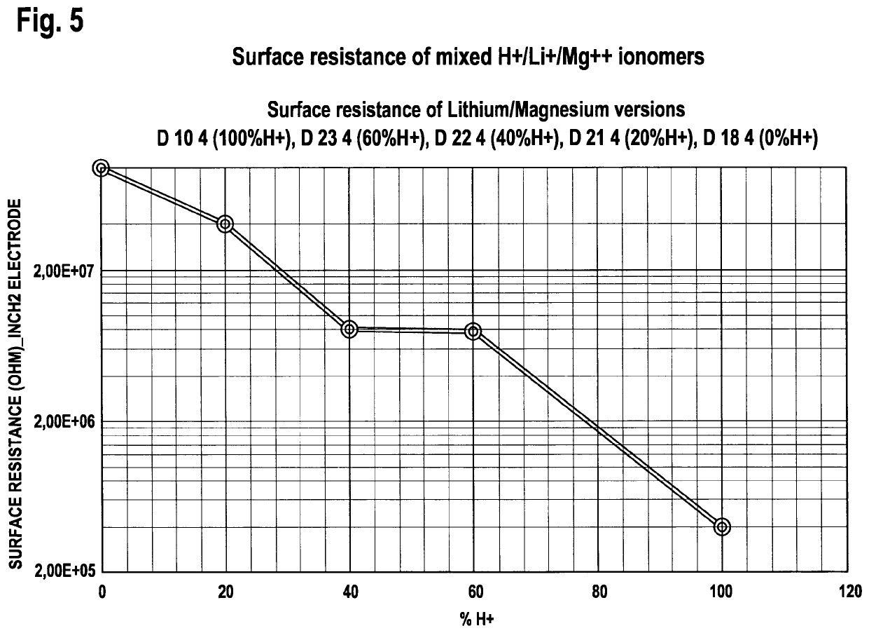

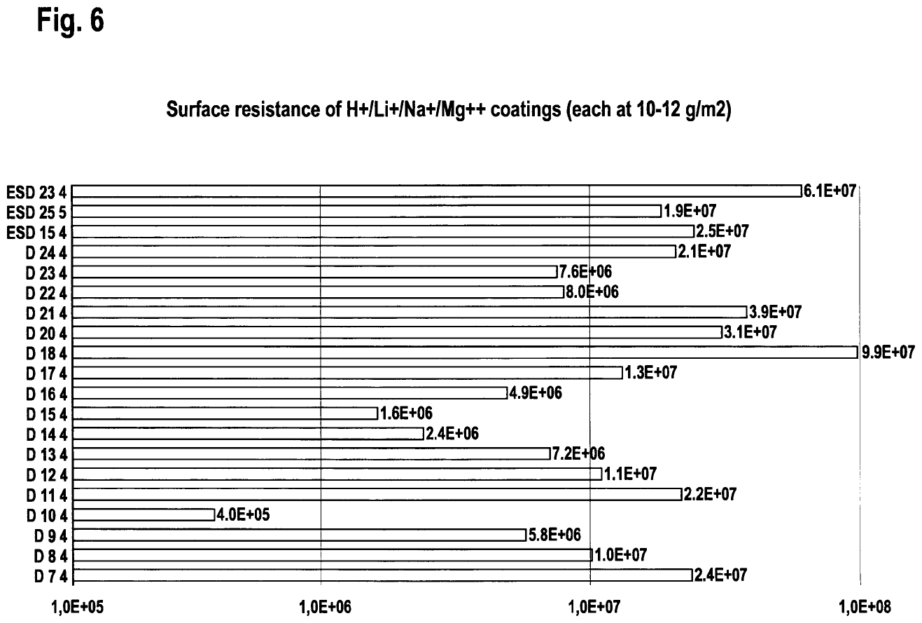

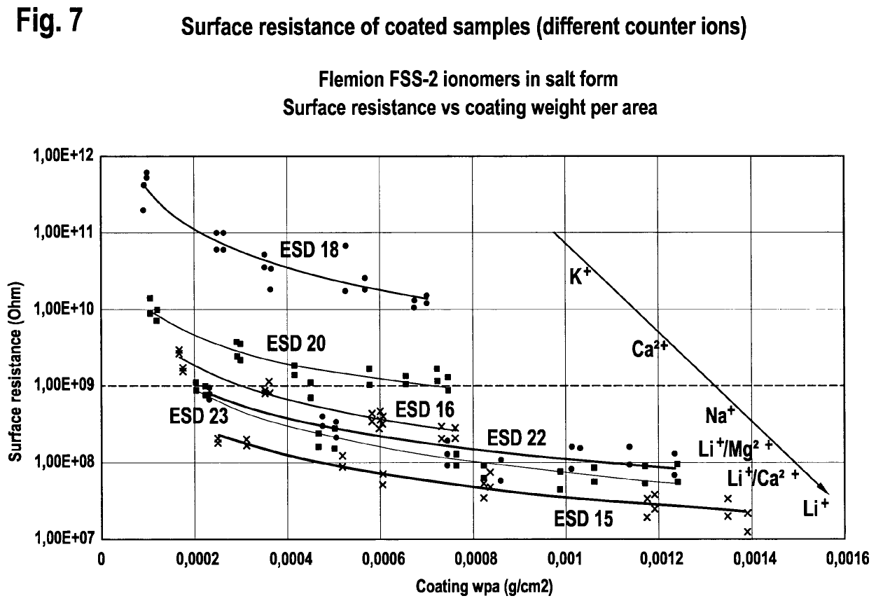

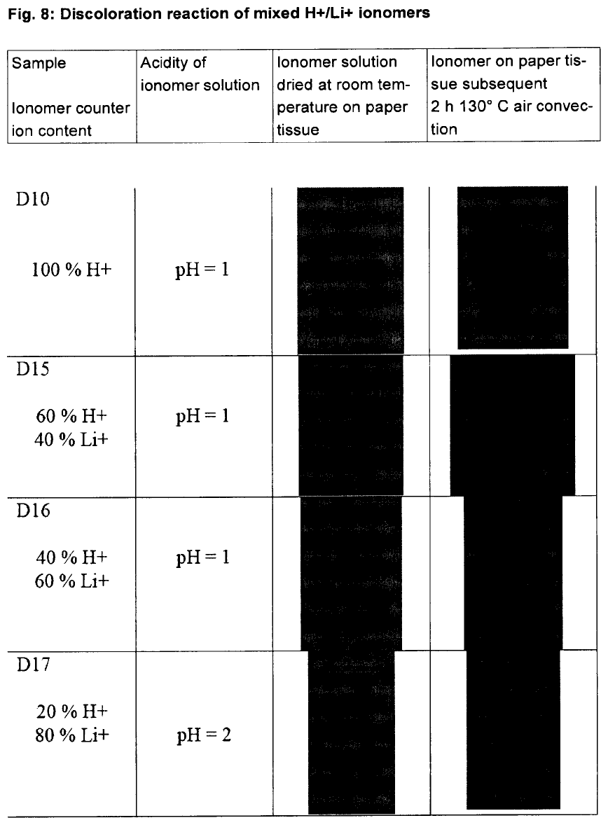

It was established that the surface resistance of ionomer coated substrates decreases with increasing coating weight. FIGS. 1A to 1O visualize this surface resistance decrease for some of the samples listed in Table 3, and also visualize that coating weights exceeding a weight per area (wpa) of about 10 g/m² have low impact on surface resistance. This is also evident from the results shown in FIG. 7 and Table 9.

As the surface resistance of ionomer coatings correlates with the amount of material on the tape surface and the air humidity during testing, a subset of samples with comparable coating laydown was selected for electrical characterization.

The surface resistance of the selected coated samples was measured with a geometry consisting of two rectangular aluminum electrodes spanning a square inch shaped surface area. The measurement is performed as follows: an electrode as described is positioned on the coated specimen and connected with a voltage generator. A one kilogram weight is applied on the electrode in order to generate a consistent initial pressure at the electrode/sample contact surface. Thereafter a voltage of 100 V DC is applied and the current through the surface layer is measured in time intervals of seconds. The results are stored as surface resistance values in digital form. For the purpose of the current comparison the surface resistance data points at a measuring time of 60 seconds were evaluated and compared.

ASTM D257-07 describing the implementation of surface resistance measurements was used as guidance for the described test methodology.
Table 4 shows the results and respective testing conditions (see also FIG. 6).

TABLE 4

| Sample | Riso[Ohm] | wpa (g/cm2) | % rH | T (° C.) |
|---|---|---|---|---|
| D 7 4 | 2.4E+07 | 0.001040 | 38.4 | 22.8 |
| D 8 4 | 1.0E+07 | 0.001078 | 38.4 | 22.8 |
| D 9 4 | 5.8E+06 | 0.001065 | 38.4 | 22.8 |
| D 10 4 | 4.0E+05 | 0.001169 | 38.4 | 22.8 |
| D 11 4 | 2.2E+07 | 0.001147 | 38.4 | 22.8 |
| D 12 4 | 1.1E+07 | 0.001069 | 38.4 | 22.8 |
| D 13 4 | 7.2E+06 | 0.001102 | 38.4 | 22.8 |
| D 14 4 | 2.4E+06 | 0.001062 | 38.4 | 22.9 |
| D 15 4 | 1.6E+06 | 0.001114 | 38.2 | 23.0 |
| D 16 4 | 4.9E+06 | 0.001055 | 38.1 | 23.0 |
| D 17 4 | 1.3E+07 | 0.001085 | 38.2 | 23.0 |
| D 18 4 | 9.9E+07 | 0.001042 | 38.5 | 23.0 |
| D 20 4 | 3.1E+07 | 0.001048 | 38.6 | 23.0 |
| D 21 4 | 3.9E+07 | 0.001062 | 38.3 | 23.0 |
| D 22 4 | 8.0E+06 | 0.001135 | 38.6 | 23.0 |
| D 23 4 | 7.6E+06 | 0.001111 | 38.3 | 23.0 |
| D 24 4 | 2.1E+07 | 0.001098 | 37.9 | 23.0 |
| ESD 15 4 | 2.5E+07 | 0.0012 | 41.4 | 22.0 |
| ESD 25 5 | 1.9E+07 | 0.00117 | 50.8 | 23.8 |
| ESD 23 4 | 6.1E+07 | 0.001061 | 41.8 | 23.4 |

FIGS. 2 to 5 and corresponding Tables 5 to 8 illustrate surface resistances of samples having coatings with different sulfonic acid: sulfonate ratios and different counter ions.

FIG. 2 and Table 5 compare coatings having 100%, 60%, 40%, and 20% sulfonic acid groups, the remainder being sulfonate groups having lithium has a counter ion.

FIG. 3 and Table 6 compare coatings having 100%, 60%, 40%, and 20% sulfonic acid groups, the remainder being sulfonate groups having sodium as a counter ion.

FIG. 4 and Table 7 compare coatings having 100%, 60%, 40%, and 20% sulfonic acid groups, the remainder being sulfonate groups having both lithium and sodium as counter ions.

FIG. 5 and Table 8 coatings having 100%, 60%, 40%, 20%, and 0% sulfonic acid groups, the remainder being sulfonate groups having both lithium and magnesium as counter ions.

FIG. 6 visualizes the results for all coatings shown in FIGS. 2 to 5, and some further coatings (see Table 4).

It is evident that the surface resistance decreases with increasing ratio of sulfonic acid groups to sulfonate groups. Furthermore, when coatings having the same ratio of sulfonic acid groups to sulfonate groups are compared, coatings having lithium as a counter ion yield the lowest surface resistance, and also coatings having sodium as counter ion yield very good results. Coatings containing both lithium and sodium as counter ions perform better than coatings containing lithium in combination with a different counter ion.

Therefore, from the view point of surface resistance, it appears desirable to use ionomers having 100% sulfonic acid groups, but it has been shown, that ionomers comprising sulfonate groups may also provide low surface resistance, in particular, when lithium is used as a counter ion.

In tables 5 to 8 and FIGS. 1A to 1O and 2 to 5, numerical values are indicated in German style (with e.g., 0,000200 g/cm² meaning 200 μg/cm²).

TABLE 5

| Sample | % H+ | Riso[Ohm] | wpa (g/cm2) | % rH | T (° C.) |
|---|---|---|---|---|---|
| D 10 4 | 100 | 4.02E+05 | 0.001170 | 38.4 | 22.8 |
| D 15 4 | 60 | 1.64E+06 | 0.001115 | 38.2 | 23 |
| D 16 4 | 40 | 4.94E+06 | 0.001056 | 38.1 | 23 |
| D 17 4 | 20 | 1.33E+07 | 0.001086 | 38.2 | 23 |

TABLE 6

| Sample | % H+ | Riso[Ohm] | wpa (g/cm2) | % rH | T (° C.) |
|---|---|---|---|---|---|
| D 10 4 | 100 | 4.02E+05 | 0.001170 | 38.4 | 22.8 |
| D 9 4 | 60 | 5.81E+06 | 0.001065 | 38.4 | 22.8 |
| D 8 4 | 40 | 1.02E+07 | 0.001079 | 38.4 | 22.8 |
| D 7 4 | 20 | 2.41E+07 | 0.001040 | 38.4 | 22.8 |

TABLE 7

| Sample | % H+ | Riso[Ohm] | wpa (g/cm2) | % rH | T (° C.) |
|---|---|---|---|---|---|
| D 10 4 | 100 | 4.02E+05 | 0.001170 | 38.4 | 22.8 |
| D 14 4 | 60 | 2.41E+06 | 0.001062 | 38.4 | 22.9 |
| D 13 4 | 40 | 7.17E+06 | 0.001103 | 38.4 | 22.8 |
| D 12 4 | 20 | 1.11E+07 | 0.001069 | 38.4 | 22.8 |

TABLE 8

| Sample | % H+ | Riso[Ohm] | wpa (g/cm2) | % rH | T (° C.) |
|---|---|---|---|---|---|
| D 10 4 | 100 | 4.02E+05 | 0.001170 | 38.4 | 22.8 |
| D 23 4 | 60 | 7.64E+06 | 0.001112 | 38.3 | 23 |
| D 22 4 | 40 | 8.03E+06 | 0.001135 | 38.6 | 23 |
| D 21 4 | 20 | 3.85E+07 | 0.001062 | 38.3 | 23 |
| D 18 4 | 0 | 9.92E+07 | 0.001043 | 38.5 | 23 |

The superiority of lithium, sodium, magnesium and calcium as counter ions is illustrated by FIG. 7. FIG. 7 shows the surface resistance of ePTFE membranes coated with Flemion FSS-2 ionomers having different counter ions versus coating weight per area. The samples were prepared as described in Examples 1 and 2, and the particulars of the coating formulation are indicated in Table 9. The straight line visualizes the influence of the counter ion/counter ion combination on conductivity. In FIG. 7, numerical values are indicated in German style.

TABLE 9

| | | | Formulation | | | | | | | | | |
|---|---|---|---|---|---|---|---|---|---|---|---|---|
| | | | | | | | | | | | Stoi- | |
| | | | | | | | | | | | chiometry | |
| | | | | | | | | | Weight | Valence | (Degree | |
| Target Ionomer | | | Solution | Solution | | Equivalent | Neutral- | Molecular | Neutral- | Factor | of | |
| | Proton | Metal | weight | conc. | Ionomer | weight | ization | weight | ization | Counter- | neutral- | Weight |
| Sample | Content | Counterion | Ionomer | Ionomer | content | Ionomer | agent | of agent | agent | ion | ization) | Water |
| | | Li+ | 20 | 10 | 2 | 909 | LiAceta- | 102.02 | 0.2193 | 1 | 0.98 | 4 |
| | | | | | | | tex2H2O | | | | | |
| ESD 15 | 2 | | | | | | | | | | | |
| | | Na+ | 20 | 10 | 2 | 909 | NaHydroxide | 40.0 | 0.0860 | 1 | 0.98 | 8 |
| ESD 16 | 2 | | | | | | | | | | | +10 g |
| | | | | | | | | | | | | isopro- |
| | | | | | | | | | | | | panol |
| | | K+ | 20 | 10 | 2 | 909 | KAcetate | 98.14 | 0.2110 | 1 | 0.98 | 8 |
| ESD 18 | 2 | | | | | | | | | | | +10 g |
| | | | | | | | | | | | | isopro- |
| | | | | | | | | | | | | panol |
| | | Ca++ | 20 | 10 | 2 | 909 | CaAcetatex- | 158.17 | 0.1700 | 2 | 0.98 | 8 |
| | | | | | | | H2O | | | | | |
| ESD 20 | 2 | | | | | | | | | | | |
| | | Li+ | 20 | 10 | 1 | 909 | LiAceta- | 102.02 | 0.1097 | 1 | 0.98 | 6 |
| | | | | | | | tex2H2O | | | | | |
| ESD 22 | 2 | Mg++ | | | 1 | 909 | MgAcetate*4 | 214.45 | 0.1153 | 2 | 0.98 | |
| | | | | | | | H2O | | | | | |
| | | Li+ | 20 | 10 | 1 | 909 | LiAceta- | 102.02 | 0.1097 | 1 | 0.98 | 6 |
| | | | | | | | tex2H2O | | | | | |
| ESD 23 | 2 | Ca++ | | | 1 | 909 | CaAcetatex- | 158.17 | 0.0850 | 2 | 0.98 | |
| | | | | | | | H2O | | | | | |
| | (%) | | w (g) | w % | w (g) | Mw (g/mol) | | Mw (g/mol) | w (g) | | | w (g) |

The comparison of specimen samples having ionomer coatings comprising different counter ions, as illustrated in FIG. 7, proves that the counter ions and counter ion combinations, respectively, used in the present invention are superior to different counter ion such as exemplified by potassium. For example, when comparing coatings comprising lithium to coatings comprising potassium as counter ion, the surface resistance achieved with lithium is more than 2 orders of magnitude lower than the surface resistance achieved with potassium as the counter ion.

### EXAMPLE 4

### Discoloration of Coated ePTFE Tape

The unintended interactions of ionomer coatings with contacting materials were investigated by a worst case test procedure. Ionomer solutions described in the previous sections were added to paper tissue which reacts rapidly with H+ based ionomers generating an intense discoloration effect by a reaction of sulfonic acid with cellulose and paper additives present at its surface. The staining reaction is interpreted as an effective indicator for unintended ionomer reactions.

The procedure had been performed as follows: Some drops of the polymer solutions according to Table 2 were added onto paper tissue and dried at room temperature for 3 hours. Then the impregnated paper was aged at a temperature of 130° C. for 2 hours in a forced air convection oven. During this time frame the indicator paper shows, depending on the coating composition, different degrees of yellowing which strongly correlates with the concentration of H+in the ionomer used.

FIGS. 8 to 11 compare ionomer solutions used for preparing the coatings, the surface resistances of which are shown in FIGS. 2 to 5. Thus, the results shown in FIG. 8 must be compared to the results shown in FIG. 2, the results shown in the FIG. 9 must be compared to the results shown in FIG. 3, the results in FIG. 10 must be compared to the results in shown in FIG. 4, and the results shown in FIG. 11 must be compared to the results shown in FIG. 5.

It is evident from FIGS. 8 to 11 that discoloration increases with increasing ratio of sulfonic acid groups to sulfonate groups. In particular after aging at elevated temperature discoloration was dramatic in the case of ionomers having a high sulfonic acid content. Therefore, from the view point of discoloration, it appears desirable to have a low sulfonic acid content. When comparing surface resistances and discoloration effects, it can be established that ionomers having a molar ratio of sulfonic acid groups to sulfonate groups in a range from about 2:8 to 2:3, and having lithium as a counter ion, are most advantageous.

1.-9. (canceled)

10. An article comprising:
a polymeric substrate; and
an antistatic coating thereon,
wherein the article comprises a cable cover, and
wherein the coating is formed from a coating composition comprising:
an ionomer having a polymer backbone and side chains.
wherein the side chains comprise ionic groups in an acid form and ionic groups in a salt form, wherein the ionic groups in the acid form are sulfonic acid groups and the ionic groups in the salt form are sulfonate groups,
wherein from 50 to 80% of the ionic groups are sulfonate groups, and
wherein the sulfonate groups have counter ions M selected from the group consisting of lithium, sodium, magnesium, calcium, and mixtures thereof;
wherein the ionomer is a fluorionomer;
wherein the fluorionomer is a copolymer of tetrafluorethylene (F₂C=CF₂) and perfluorinated vinyl ether.

11. The article of claim 10, wherein the polymeric substrate is porous, and wherein the antistatic coating is at least partially impregnated within pores of the polymeric substrate.

12. The article of claim 10, wherein the polymeric substrate is a perfluorinated polymer or a partially fluorinated polymer.

13. The article of claim 10, wherein the polymeric substrate is in tape form or sheet form having two main surfaces, and wherein the antistatic coating is provided on one or on both surfaces of the polymeric substrate.

14. The article of claim 10, wherein the polymeric substrate is in tape form or sheet form having two main surfaces, wherein the antistatic coating is provided on one of the main surfaces, and wherein an adhesive layer is provided on the opposing main surface.

15. The article of claim 10, wherein the article is a cable cover.

16. The article of claim 10, wherein two cable covers are laminated together with an adhesive therebetween to form a cable jacket having an electrostatic coating.

17. The article of claim 10, further comprising a cable comprising an outermost electrically non-conductive layer and an antistatic coating thereon.

18. The article of claim 17, wherein the cable comprises at least one of a conductor, a conduit, or a channel.

19. The article of claim 10, wherein the polymeric substrate is ePTFE provided on a conductor.

20. The article of claim 10, wherein the polymeric substrate is ePTFE provided on an arrangement comprising at least one of a wire, a conductor, or a conduit.
